(19) United States
(12) Patent Application Publication
(10) Pub. No.: US 2015/0279547 A1
(43) Pub. Date: Oct. 1, 2015

(54) COIL COMPONENT AND MANUFACTURING METHOD THEREOF

(71) Applicant: SAMSUNG ELECTRO-MECHANICS CO., LTD., Suwon-Si (KR)

(72) Inventors: Geun Young PARK, Suwon-Si (KR); Heung Gyoon CHOI, Suwon-Si (KR); Young Min LEE, Suwon-Si (KR); Jae Gen EOM, Suwon-Si (KR); Young Seung NOH, Suwon-Si (KR)

(73) Assignee: SAMSUNG ELECTRO-MECHANICS CO., LTD., Suwon-Si (KR)

(21) Appl. No.: 14/641,825

(22) Filed: Mar. 9, 2015

(30) Foreign Application Priority Data
Apr. 1, 2014 (KR) 10-2014-0038881
Oct. 2, 2014 (KR) 10-2014-0133330

(51) Int. Cl. H01F 27/28; H05K 1/16; H05K 1/11; H01F 41/02; H01F 27/29; H01F 27/32; H05K 3/30; H05K 1/18; H01F 27/24

(52) U.S. Cl. CPC H01F 27/2804; H05K 1/181; H05K 1/165; H05K 1/111; H01F 27/24; H01F 27/29; H01F 27/324; H05K 3/30; H01F 41/02; H05K 2201/1003; H05K 2201/09972; H01F 2027/2809; H01F 2027/297

(57) ABSTRACT

A coil component capable of being easily manufactured while significantly reducing a size thereof, and a manufacturing method thereof, the coil component including: a first coil part including a stacked substrate on which a first coil pattern is formed; a second coil part including a main substrate on which a second coil pattern is formed and a plurality of electronic components are mounted; a core penetrating through the first and second coil parts and coupled to the first and second coil parts; and an insulating member securing an insulation distance between the second coil pattern and the electronic components mounted on the main substrate.

### CROSS-REFERENCE TO RELATED APPLICATIONS

This application claims the priorities and benefits of Korean Patent Application Nos. 10-2014-0038881 filed on Apr. 1, 2014 and 10-2014-0133330 filed on Oct. 2, 2014, with the Korean Intellectual Property Office, the disclosures of which are incorporated herein by reference.

### BACKGROUND

The present inventive concept relates to a coil component able to be easily manufactured while having a significantly reduced size, and a manufacturing method thereof.

An electronic device such as a display device or an adapter is provided with a power supply apparatus that converts an alternating current (AC) power into a direct current (DC) power.

A power supply apparatus commonly has a coil component for converting AC power into DC power mounted thereon, that is, a transformer. In this regard, a transformer according to the related art generally has a structure in which a coil is wound around a bobbin and a core is coupled to the bobbin.

Therefore, since a coil component according to the related art commonly has a wire type coil wound around a bobbin, there may be a limit in reducing a size of the bobbin. Therefore, there may be a limit in reducing an overall size of the coil component.

In addition, in the case in which the coil component is miniaturized, it may be difficult to secure sufficient insulation between primary and secondary sides.

### RELATED ART DOCUMENT

Japanese Patent Laid-Open Publication No. 2009-135456

### SUMMARY

An aspect of the present inventive concept may provide a coil component having a significantly reduced size, and a manufacturing method thereof.

An aspect of the present inventive concept may also provide a coil component providing a coil part using a main substrate, and a manufacturing method thereof.

An aspect of the present inventive concept may also provide a coil component capable of performing an alternating current (AC)-direct current (DC) power conversion while having a relatively small size, and a manufacturing method thereof.

According to an aspect of the present inventive concept, a coil component may include: a first coil part including a stacked substrate on which a first coil pattern is formed; a second coil part including a main substrate on which a second coil pattern is formed and a plurality of electronic components are mounted; a core penetrating through the first and second coil parts and coupled to the first and second coil parts; and an insulating member securing an insulation distance between the second coil pattern and the electronic components mounted on the main substrate.

The insulating member may be formed as an insulating cover or a molding part.

According to another aspect of the present inventive concept, a coil component may include: a main substrate on which electronic components of a primary side and electronic components of a secondary side are mounted together with each other and a second coil pattern is formed; and a stacked substrate having a first coil pattern formed thereon and mounted on the main substrate.

The stacked substrate and the electronic components on the primary side may be classified as a primary region, and the second coil pattern and the electronic components on the secondary side may be classified as a secondary region.

### BRIEF DESCRIPTION OF DRAWINGS

The above and other aspects, features and other advantages of the present inventive concept will be more clearly understood from the following detailed description taken in conjunction with the accompanying drawings, in which:

FIG. 1 is a perspective view schematically illustrating a coil component according to an exemplary embodiment in the present inventive concept;

FIG. 2 is a plan view of the coil component illustrated in FIG. 1;

FIG. 3 is an exploded perspective view of the coil component illustrated in FIG. 1;

FIG. 4 is a partial bottom perspective view of the coil component illustrated in FIG. 1;

FIG. 5 is a perspective view schematically illustrating a coil component according to another exemplary embodiment in the present inventive concept;

FIG. 6 is a plan view of the coil component illustrated in FIG. 5;

FIG. 7 is a perspective view schematically illustrating a coil component according to another exemplary embodiment in the present inventive concept;

FIG. 8 is a plan view of the coil component illustrated in FIG. 7;

FIG. 9 is an exploded perspective view of the coil component illustrated in FIG. 7;

FIG. 10 is a cross-sectional view schematically illustrating a cross-section of the coil component illustrated in FIG. 7 according to another exemplary embodiment in the present inventive concept;

FIG. 11 is a perspective view schematically illustrating a coil component according to another exemplary embodiment in the present inventive concept;

FIG. 12 is an exploded perspective view of the coil component illustrated in FIG. 11;

FIG. 13 is a perspective view schematically illustrating a first coil part of the coil component illustrated in FIG. 11;

FIG. 14 is a perspective view schematically illustrating a coil component according to another exemplary embodiment in the present inventive concept;

FIG. 15 is a perspective view schematically illustrating a first coil part of the coil component illustrated in FIG. 14;

FIG. 16 is a side view schematically illustrating a coil component according to another exemplary embodiment in the present inventive concept; and

FIG. 17 is a plan view of the coil component illustrated in FIG. 16.

### DETAILED DESCRIPTION

Exemplary embodiments of the present inventive concept will now be described in detail with reference to the accompanying drawings.

The inventive concept may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art.

In the drawings, the shapes and dimensions of elements may be exaggerated for clarity, and the same reference numerals will be used throughout to designate the same or like elements.

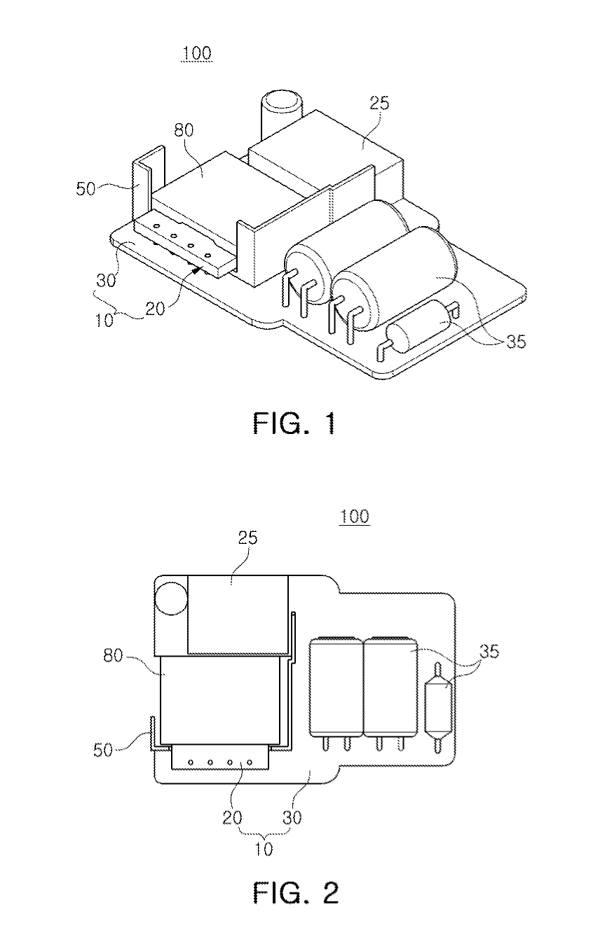

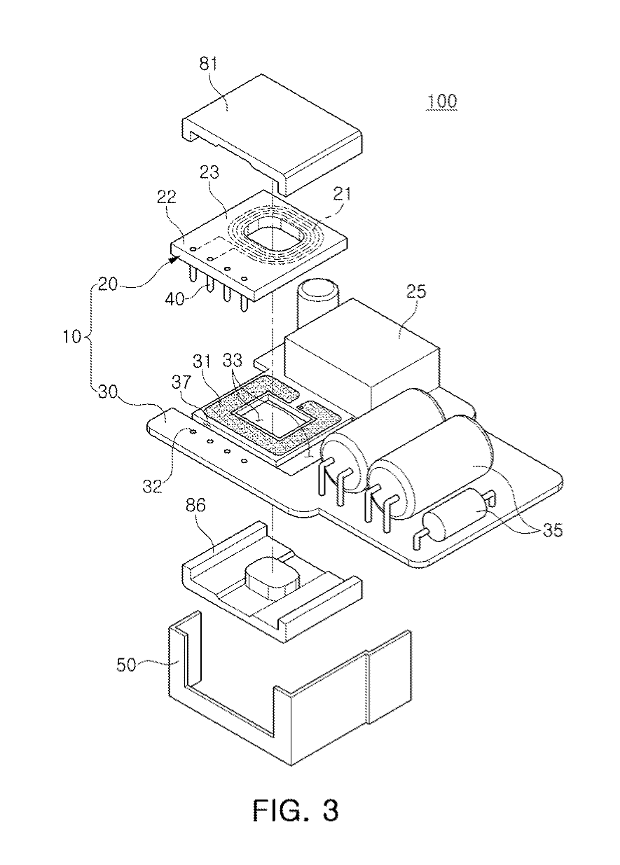

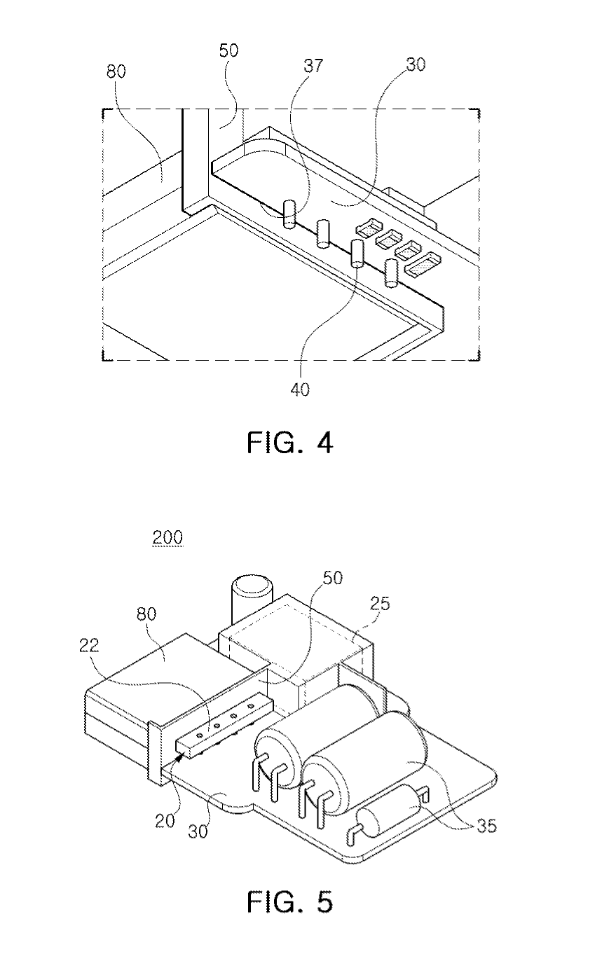

FIG. 1 is a perspective view schematically illustrating a coil component according to an exemplary embodiment in the present inventive concept; FIG. 2 is a plan view of the coil component illustrated in FIG. 1; FIG. 3 is an exploded perspective view of the coil component illustrated in FIG. 1; and FIG. 4 is a partial bottom perspective view of the coil component illustrated in FIG. 1.

A coil component according to an exemplary embodiment in the present inventive concept, a coil component provided in a power supply apparatus mounted in a TV or provided in a charging adapter, or the like, may be a transformer transforming AC voltage into DC voltage.

Referring to FIGS. 1 through 4, a coil component 100 according to the present exemplary embodiment may be configured to include a core 80, a coil part 10, and an insulating member 50.

The core 80 may be coupled to the coil part 10, wherein first and second cores 81 and 86 may be coupled to each other to form a complete single core 80.

The first and second cores 81 and 86 may be formed to have the same shape and may include a middle foot part inserted into the coil part 10 and an outer foot part disposed outwardly of the coil part 10.

In the present exemplary embodiment, a case in which the core 80 is formed in an overall parallelepipedal shape is described by way of example. However, in the present exemplary embodiment, the shape of the core is not limited thereto, but may be variously modified as necessary.

In addition, although the core 80 is illustrated as an E-E type core in the present exemplary embodiment, the core 80 is not particularly limited thereto. For example, the core 80 may be an E-I type core, a U-U type core, a U-I type core, or the like.

The core 80 may be formed of ferrite having relatively high permeability, a low loss, high saturation magnetic flux density, high stability, and a low production cost, as compared to other materials.

For example, the core 80 according to the present exemplary embodiment may be formed of nickel (Ni) based ferrite or manganese (Mn) based ferrite.

The coil part 10 may include a first coil part 20 and a second coil part 30.

The first coil part 20 may be provided to have a form of a single insulating layer on which a conductor pattern (not illustrated) is formed, or a stacked substrate on which a plurality of insulating layers are stacked to forma first coil pattern.

Here, the stacked substrate may be provided as a flexible substrate such as a printed circuit board (PCB) or a film substrate, but the type of the stacked substrate is not limited thereto.

For example, the stacked substrate according to the present exemplary embodiment may be a multilayer stacked substrate on which three or more of plurality of conductor pattern layers are stacked. In addition, a plurality of conductor pattern layers may be provided with a plurality of coil turns, for example, 36 turns, forming the first coil pattern as indicated by reference numeral 21 in FIG. 3. In this case, the plurality of coil turns may be formed on several conductor pattern layers to be distributed thereto, respectively.

In addition, the conductor pattern layers may be electrically connected to each other by a conductive via (not illustrated), or the like, penetrating through the insulation layer.

The first coil part 20 according to the present exemplary embodiment may be used as a primary coil. Therefore, the second coil part 30 may be used as a secondary coil. However, the present inventive concept is not limited thereto and is variously modified. For example, the second coil part 30 may be used as the primary coil, and so forth.

The first coil part 20 according to the present exemplary embodiment may be formed of the stacked substrate having an overall rectangular shape and may have a through hole into which the core 80 is inserted, wherein the through hole is formed in the first coil part 20.

In addition, the stacked substrate may include a pattern part 23 on which the first coil pattern 21 is formed, and a terminal part 22 formed on one side of the pattern part 23 to electrically connect the first coil pattern 21 externally.

The terminal part 22 may be fastened with terminal pins 40 for creating an electrical connection to the main substrate 30. However, the manner of connecting the first coil part 20 and the main substrate 30 to each other is not limited to the terminal pins 40, and may be variously modified as long as the first coil part 20 and the main substrate 30 are electrically connected to each other, using such as a solder bump, a solder ball, a connector, or the like.

The second coil part 30 may be configured of the main substrate 30 on which the second coil pattern 31 is formed. In this regard, the second coil part 30 and the main substrate 30 are the same component; therefore, the same reference numeral will be used to refer to the second coil part and the main substrate.

The main substrate 30 refers to a mother board to which the coil component 100 according to the present inventive concept is electrically connected, and may be, for example, a main substrate of the power supply apparatus or an adapter.

Therefore, the second coil pattern 31 according to the present exemplary embodiment may be formed directly on the main substrate 30 rather than being separately manufactured, and may be simultaneously formed during a process in which a wiring pattern of the main substrate 30 is formed.

The main substrate 30 may have a plurality of terminal pads 32 formed thereon and the respective terminal pads 32 may have the terminal pins 40 bonded thereto, wherein the terminal pins 40 may be connected to the first coil part 20. Therefore, the terminal pins 40 may be bonded to the main substrate 30 to electrically connect the first coil pattern 21 of the first coil part 20 and the main substrate 30 to each other.

Meanwhile, various modifications thereof may include, for example, forming the terminal pad 32 of the main substrate 30 as a through hole rather than a form of a pad, and inserting the terminal pins 40 into the through holes, respectively, and bonding the terminal pins 40 to the main substrate 30.

In addition, the main substrate 30 may have core insertion parts 33 formed therein. The core insertion part 33, a space of the main substrate 30 for inserting the core 80 and an insulating cover 50 thereinto, may be formed as a through hole or a groove.

Therefore, the core insertion parts 33 may be formed as a plurality of holes having a size and shape corresponding to that of the middle foot part or the outer foot part of the core 80.

In addition, the main substrate 30 according to the present exemplary embodiment may be a double-sided printed wiring board having the second coil patterns 31 formed on both surfaces of a single insulation layer. Therefore, the second coil pattern 31 of the main substrate 30 may include the number of coil turns, for example, three turns, smaller than the number of coil turns of the first coil pattern 21 formed on the stacked substrate of the first coil part 20, and a width of each coil turn of the second coil pattern 31 may be greater than a width of each coil turn of the first coil pattern 21.

In addition, the coil component 100 according to the present exemplary embodiment may include an insulating member.

The insulating member may secure insulation between the second coil pattern 31 and electronic components 35 mounted on the main substrate 30. In addition, the insulating member may secure insulation between the terminal pins 40 bonded to the first coil part 20 and the second coil pattern 31 of the second coil part 30.

In addition, the insulating member may be interposed between electronic components 35 on a primary side of the coil component 100 and electronic components 25 on a secondary side of the coil component 100 which are mounted on the main substrate 30, thereby securing insulation therebetween.

The insulating member according to the present exemplary embodiment may be an insulating cover 50.

The insulating cover 50 may be provided to secure insulation between a primary side of the coil component 100 and a secondary side of the coil component 100 according to the present exemplary embodiment. Therefore, the insulating cover 50 may be disposed to be interposed between the electronic components 35 on the primary side and the secondary side electronic components 25.

The insulating cover 50 may be formed of an insulating material such as a resin and side walls of the insulating cover 50 used for blocking may be formed in several directions for insulation.

In addition, a case in which a universal serial bus (USB) terminal 25 is electrically connected to the secondary coil is illustrated in the present exemplary embodiment, by way of example. Therefore, the insulating cover 50 may be coupled to the main substrate 30 in a form in which a portion of the side wall of the insulating cover 50 is interposed between the USB terminal 25, that is, the secondary side electronic component, and the primary side electronic components 35.

In addition, the insulating cover 50 may insulate between the primary coil and the secondary coil. Since the first coil part 20 has the first coil pattern 21 formed by the wiring pattern within the stacked substrate, insulation between the first coil part 20 and the second coil part 30 may be secured by the insulating layers constituting the stacked substrate. However, since the terminal pins 40, namely, conductors, electrically connected to the first coil pattern 21 are completely exposed externally, an insulation distance and a creeping distance between the first coil pattern 21 and the second coil pattern 31 need to be secured.

To this end, the insulating cover 50 according to the present exemplary embodiment may be interposed between the terminal pins 40 on the primary side of the coil component 100 and the coil pattern on the secondary side of the coil component 100, that is, the second coil pattern 31, to secure insulation therebetween.

In addition, the main substrate 30 according to the present exemplary embodiment may have a cut part 37 having a cut shape formed between the second coil pattern 31 of the second coil part 30 and the terminal pad 32. In addition, the cut part may have the insulating cover 50 partially inserted thereinto.

In this case, the insulating cover 50 may be inserted into the cut part 37 so that a portion of the insulating cover 50 protrudes outwardly of the main substrate 30. For example, as illustrated in FIG. 4, the insulating cover 50 may be coupled to the main substrate 30 to protrude both upwardly and downwardly of the main substrate 30.

As a result, the insulation distance and the creeping distance between the second coil pattern 31, which is on the secondary side of the coil component 100, and the terminal pins 40, which are on the primary side of the coil component 100, may be secured.

Although not clearly illustrated in FIG. 4, the cut part 37 may also be formed between the electronic components 35 on the primary side of the coil component 100 and the USB terminal 25, which is on the secondary side of the coil component 100, and the insulating cover 50 may also be configured to be inserted into the cut part.

Meanwhile, the insulating cover 50 according to the present exemplary embodiment is not limited to the illustrated example, and may be variously modified based on a size, a disposition state, or the like, of the electronic components.

In addition, although a case in which the first coil part 20 is stacked and coupled onto the second coil part 30 is described in the present exemplary embodiment by way of example, the configuration of the present inventive concept is not limited thereto. Various modifications of disposition manner of the first coil part 20 and the second coil part 30 may include, for example, stacking the first coil part 20 below the second coil part 30, or disposing the first coil part 20 in an internal space of the second coil part 30 by forming the internal space of the second coil part 30 centrally of the second coil part 30, and so forth.

The coil component according to the present exemplary embodiment configured as described above may provide the coil component using a portion of the main substrate. Therefore, since the second coil part is not manufactured as a separate component, costs for manufacturing the coil component may be relatively reduced.

In addition, the coil component according to the present exemplary embodiment may be a transformer which may be used for the AC-DC transformation. In addition, the electronic components on the primary side of the coil component and the electronic components on the secondary side of the coil component may be mounted together with each other on the main substrate.

In the case of the AC-DC transformation, the insulation between the primary side of the coil component and the secondary side of the coil component may be significant. To this end, the coil component according to the present exemplary embodiment may secure the insulation distance and the creeping distance between the primary side of the coil component and the secondary side of the coil component by forming the cut part in the main substrate and then inserting the insulating cover thereinto. Therefore, the coil component may also be easily used for the AC-DC transformation.

In addition, the coil component according to the present exemplary embodiment may have the main substrate on which the electronic components on the primary side of the coil component, the electronic components on the secondary side of the coil component, and the stacked substrate are mounted together thereon, wherein the second coil pattern, which is on the secondary side of the coil component, may be formed on the main substrate. In addition, the stacked substrate may have the first coil pattern, which is on the primary side of the coil component, formed thereon.

In addition, since the core penetrating through the main substrate and the stacked substrate and coupled thereto is disposed to be adjacent to the second coil pattern rather than the first coil pattern, the core may be classified as a secondary side.

Accordingly, the stacked substrate and the primary side electronic components may be classified as the primary side of the coil component, and the second coil pattern and the secondary side electronic components may be classified as the secondary side of the coil component. In addition, the core may be classified as the secondary side of the coil component.

As such, since the coil component according to the present exemplary embodiment may have both the primary and secondary sides of the coil component formed in the single main substrate, it may be essential to secure insulation between the primary and secondary sides of the coil component, which may be provided by the insulating member according to the present exemplary embodiment. Therefore, even in a case in which the coil component is used for transformation of a high level of current or a high level of voltage such as the AC-DC transformation, insulation may be easily secured.

Hereinafter, a manufacturing method of a coil component according to an exemplary embodiment in the present inventive concept will be described with reference to FIG. 3. In addition, the configuration of the coil component 100 described above will be described with clarity in the following description.

The main substrate 30 may be prepared. The main substrate 30 may be in a state in which the primary side electronic components 35 and the secondary side electronic components 25 are all mounted thereon.

In addition, the main substrate 30 may be the double-sided printed wiring board on which the second coil patterns 31, the core insertion parts 33, the cut part 37, and the terminal pads 32 described above are formed.

The first coil part 20 may be coupled to the main substrate 30. The first coil part 20 may be electrically and physically coupled to the main substrate 30 by fixedly bonding the terminal pins 40 to the respective terminal pads 32 of the main substrate 30, the terminal pins 40 being fastened to the terminal part 22.

Meanwhile, a case in which the terminal pins 40 are fastened to the first coil part 20 is described in the present exemplary embodiment by way of example, but conversely, the terminal pins 40 may be fastened to the main substrate 30 and may then be bonded to the first coil part 20 during a process in which the first coil part 20 is coupled to the main substrate 30.

The cores 81 and 86 may be coupled to each other. In detail, the cores 86 and 81 may be inserted into the core insertion part 33 of the main substrate 30, and may accommodate the first and second coil parts 20 and 30 therein, respectively.

The insulating cover 50 may be coupled to the main substrate 30. In this process, the insulating cover 50 may be inserted into the cut part 37 to secure the insulation distance and the creeping distance between the primary side electronic components 35 and the secondary side electronic components 25, and between the terminal pins 40 on the primary side of the coil component 100 and the second coil pattern 31 on the secondary side of the coil component 100, all which are mounted on the main substrate 30.

The coil component according to the present inventive concept as described above is not limited to the above-mentioned exemplary embodiment, but may be variously modified.

A coil component to be described below may be configured to have a structure similar to that of the coil component of the exemplary embodiment described above and may have a slight difference. Accordingly, a detailed description of the same components will be omitted, and different configuration will mainly be described in greater detail. In addition, the same reference numerals will be used to describe the same components as those in the above-mentioned exemplary embodiment.

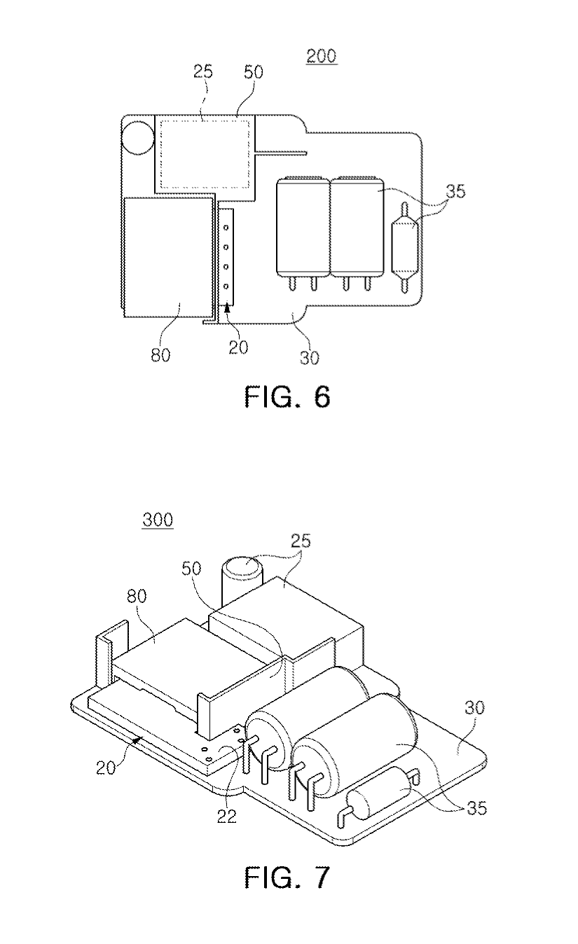

FIG. 5 is a perspective view schematically illustrating a coil component according to another exemplary embodiment in the present inventive concept; and FIG. 6 is a plan view of the coil component illustrated in FIG. 5.

Referring to FIG. 5, a coil component 200 according to the present exemplary embodiment may be different from the coil component 100 described in FIG. 1 in terms of a direction in which the terminal part 22 of the first coil part 20 is disposed. In addition, the insulating cover 50 may be formed to cover the USB terminal 25, that is, the secondary side electronic component.

In addition, the insulating cover 50 according to the present exemplary embodiment may have the side walls formed downwardly as well as upwardly of the terminal part 22 of the first coil part 20, thereby securing insulation between the terminal part 22 of the first coil part 20 and the core 80.

Similar to the above-mentioned exemplary embodiment, since the core 80 is disposed to be adjacent to the coil pattern 31 on a secondary side of the coil component 200, the core 80 may be classified as a secondary component. Therefore, insulation between the core 80 and the first coil part 20, which is on the primary side of the coil component 200 may need to be secured.

To this end, the insulating cover 50 according to the present exemplary embodiment may also be disposed between the core 80 and the terminal part 22 of the first coil part 20, thereby securing an insulation distance and a creeping distance therebetween.

The above-mentioned configuration may also be easily applied to the coil component 100 described in FIG. 1.

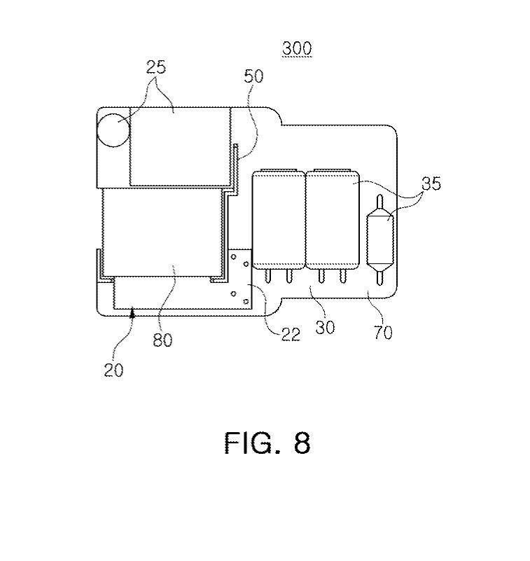

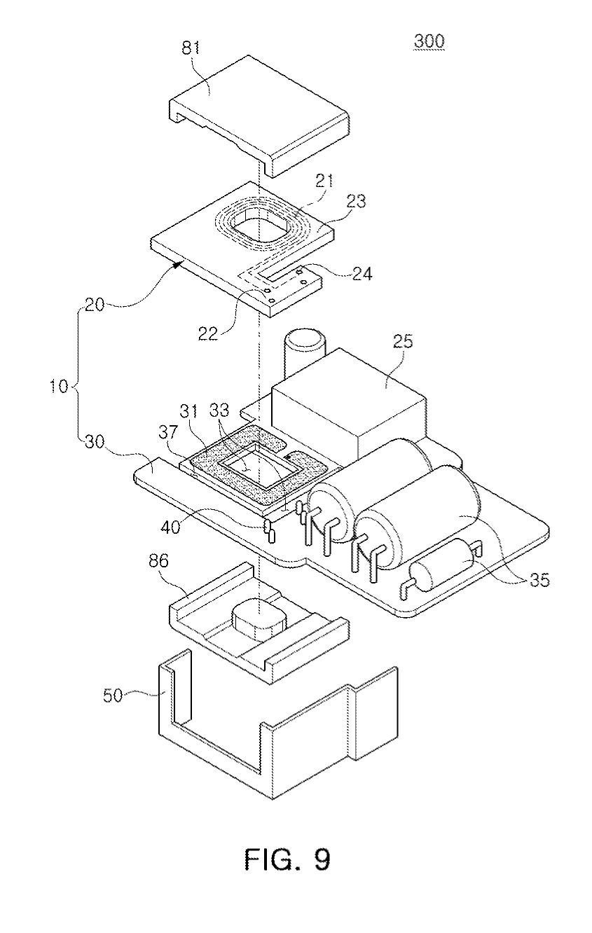

FIG. 7 is a perspective view schematically illustrating a coil component according to another exemplary embodiment in the present inventive concept; FIG. 8 is a plan view of the coil component illustrated in FIG. 7; and FIG. 9 is an exploded perspective view of the coil component illustrated in FIG. 7.

Referring to FIGS. 7 through 9, a coil component 300 according to the present exemplary embodiment is different from the above-mentioned coil components in terms of a shape of the first coil part 20.

The first coil part 20 according to the present exemplary embodiment may have the terminal part 22 protruding from the pattern part 23 to form a terminal block 22.

The terminal block 22 may be formed to protrude from one end of the pattern part 23 so as to be extended onto a side surface of the core 80 along an outer shape of the core 80. For example, the terminal block 22 may protrude from the pattern part 23 to have a shape of ‘ [symbol] ’.

Meanwhile, the terminal pins 40 according to the present exemplary embodiment may be fastened to the main substrate 30, and the first coil part 20 may have terminal holes 24 formed therein, wherein the terminal pins 40 are inserted into the terminal holes 24, respectively. Therefore, the terminal pins 40 may be inserted into the terminal holes 24 of the first coil part 20, respectively, and may be electrically connected to the first coil pattern 21 of the first coil part 20.

In addition, similar to the above-mentioned exemplary embodiment, the core 80 according to the present exemplary embodiment may also be classified as the secondary component. Therefore, in order to secure insulation between the core 80 and the first coil part 20, which is on the primary side of the coil component 200, the insulating cover 50 according to the present exemplary embodiment may be disposed between the core 80 and the terminal block 22 of the first coil part 20, thereby securing an insulation distance and a creeping distance therebetween. In this case, the side wall of the insulating cover 50 disposed between the core 80 and the terminal block 22 of the first coil part 20 may be inserted into the core insertion part 33 and the cut part 37 of the main substrate 30.

Therefore, the insulation distance and the creeping distance may be relatively reliably secured as compared to the above-mentioned exemplary embodiments.

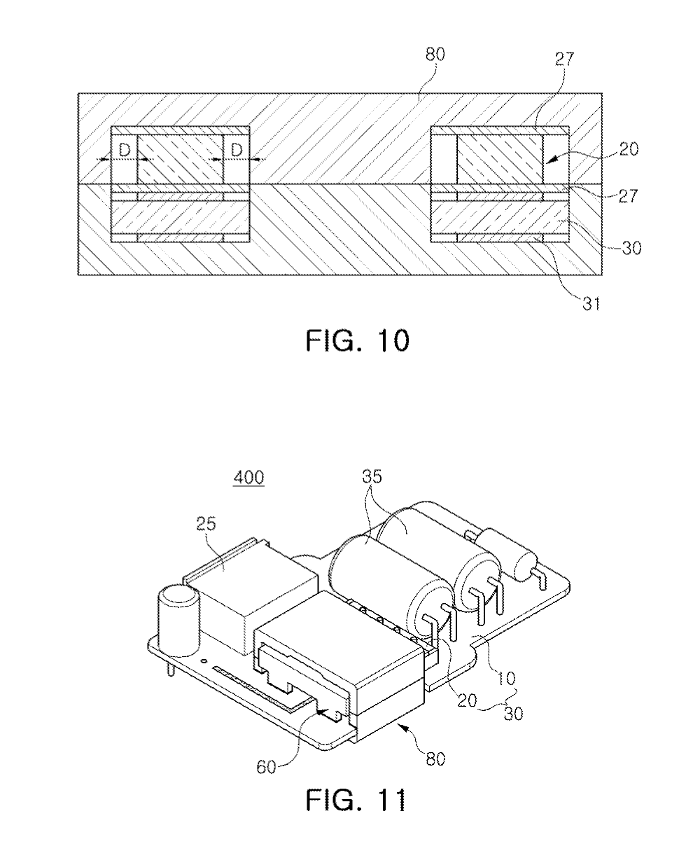

FIG. 10 is a cross-sectional view schematically illustrating a cross-section of the coil component illustrated in FIG. 7 according to another exemplary embodiment in the present inventive concept, wherein only the first coil part, the second coil part, and the core are illustrated for ease of description.

Referring to FIG. 10, the coil component 300 according to the present exemplary embodiment may include insulating films 27 for insulation between the first coil part 20 and the core 80.

The present exemplary embodiment may be applied to a case in which it is difficult to secure the insulation of the first coil part 20 only by the insulating layers constituting the stacked substrate of the first coil part 20.

In this case, an insulation distance between the core 80 classified as the secondary component and the first coil part 20, which is on the primary side of the coil component 300, also needs to be secured.

To this end, the insulating films 27 may be formed of insulating materials, and may be disposed on both surfaces of the stacked substrate of the first coil part 20, respectively. The insulating film 27 may be formed to have an area greater than that of the first coil part 20, and consequently, side surfaces of the first coil part 20 may be spaced apart from inner surfaces of the core 80 by a predetermined distance D.

Here, the distance D may be set as the insulation distance between the first coil part 20 and the core 80. Therefore, the insulating film 27 may be formed to have a size allowing for the secure insulation distance between the core 80 and the first coil part 20.

Therefore, insulation between upper and lower surfaces of the first coil part 20 and the core 80 may be secured by the insulating films 27, and the insulation between the side surfaces of the first coil part 20 and the core 80 may be secured by the spaced distance D obtained by a difference between the areas of the insulating film 27 and the first coil part 20.

As the insulating film 27 according to the present exemplary embodiment, polypropylene (PP) may be used. However, the material used for the insulating film 27 is not limited thereto.

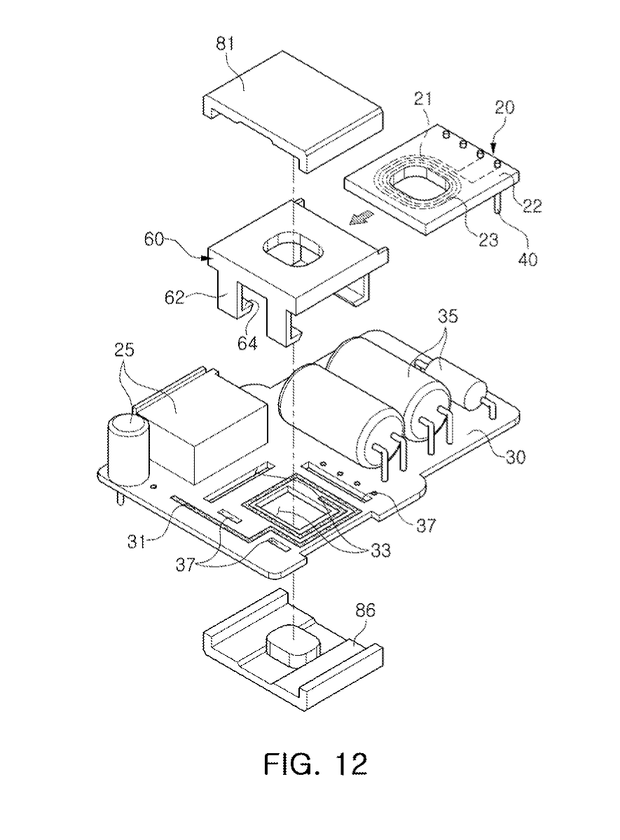

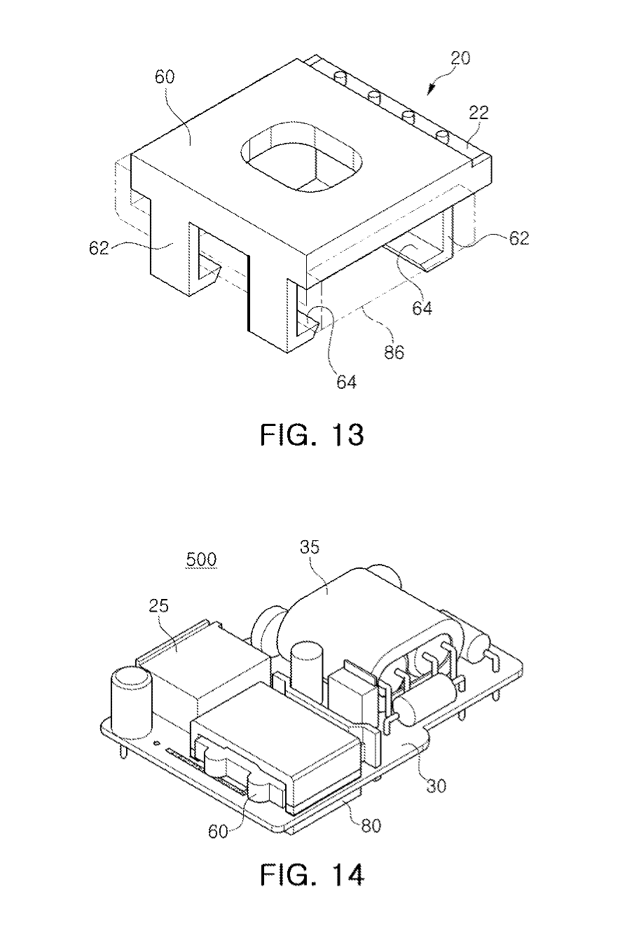

FIG. 11 is a perspective view schematically illustrating a coil component according to another exemplary embodiment in the present inventive concept; FIG. 12 is an exploded perspective view of the coil component illustrated in FIG. 11; and FIG. 13 is a perspective view schematically illustrating a first coil part of the coil component illustrated in FIG. 11.

Referring to FIGS. 11 through 13, an insulating member of a coil component 400 according to the present exemplary embodiment may be a molding part 60.

The first coil part 20 according to the present exemplary embodiment may have the pattern part 23 accommodated or embedded in the molding part 60, and portions of the first coil part 20 such as the terminal part 22 having the terminal pins 40 formed thereon, and the like, may be exposed outwardly of the molding part 60.

The molding part 60 may include at least two locking protrusions including a protrusion part 62 and a hook part 64. As illustrated in FIG. 13, the locking protrusions including the protrusion part 62 and the hook part 64 may fixedly couple at least one core, for example, the second core 86, to the molding part 60.

Therefore, the locking protrusions may include the protrusion part 62 protruding downwardly from one side of the molding part 60, and the hook part 64 protruding from an end of the protrusion part 62 toward an interior of the molding part 60.

As illustrated in FIG. 12, the locking protrusions 62 and 64 may penetrate through the main substrate 30 to be coupled to the second core 86, wherein the hook part 64 supports an outer surface, that is, a lower surface of the second core 86. Therefore, the first coil part 20, the main substrate 30, and the second core 86 may be mechanically coupled to one another by the molding part 60.

The above-mentioned molding part 60 may be formed of an insulating material such as an epoxy resin, and may be formed by disposing the first coil part 20 in a mold and then performing an injection molding process. However, the material and the manner of forming the molding part 60 are not limited thereto, but may be variously modified. For example, the molding part 60 having an interior space may be separately formed and the first coil part 20 may then be inserted into the interior space of the molding part 60, to thereby integrally form the first coil part 20 and the molding part 60.

As such, in the case in which the first coil part 20 is embedded in the molding part 60, insulation between the first coil part 20 and the second coil part 30, and between the first coil part 20 and the core 80 may be easily secured by the molding part 60. Therefore, the above-mentioned insulating cover may be omitted.

Hereinafter, a manufacturing method of the coil component according to the exemplary embodiment illustrated in FIGS. 11 through 13 will be described with reference to FIG. 12. In addition, the configuration of the coil components described above will be described with clarity in the following description.

The main substrate 30 may be prepared. The main substrate 30 may be in a state in which the electronic components 35 on the primary side of the coil component and the electronic components 25 on the secondary side of the coil component are all mounted thereon.

A coil assembly including the coil part 20 and the molding part 60 in which the first coil part 20 is partially accommodated in the molding part may be coupled to the main substrate 30. Here, the coil assembly may be manufactured by forming the first coil part 20, disposing the first coil part 20 in the mold, and forming the molding part 60 through an injection molding process.

In addition, the coil assembly may be manufactured by separately forming the molding part 60 having an interior space, inserting the first coil part 20 into the interior space of the molding part 60, and then integrating the first coil part 20 and the molding part 60 with each other.

The coil component 400 may be completed by coupling the cores 81 and 86 to each other. The cores 81 and 86 may be coupled to each other to be inserted into the core insertion part 33 of the main substrate 30 and to penetrate through the main substrate 30 and the stacked substrate.

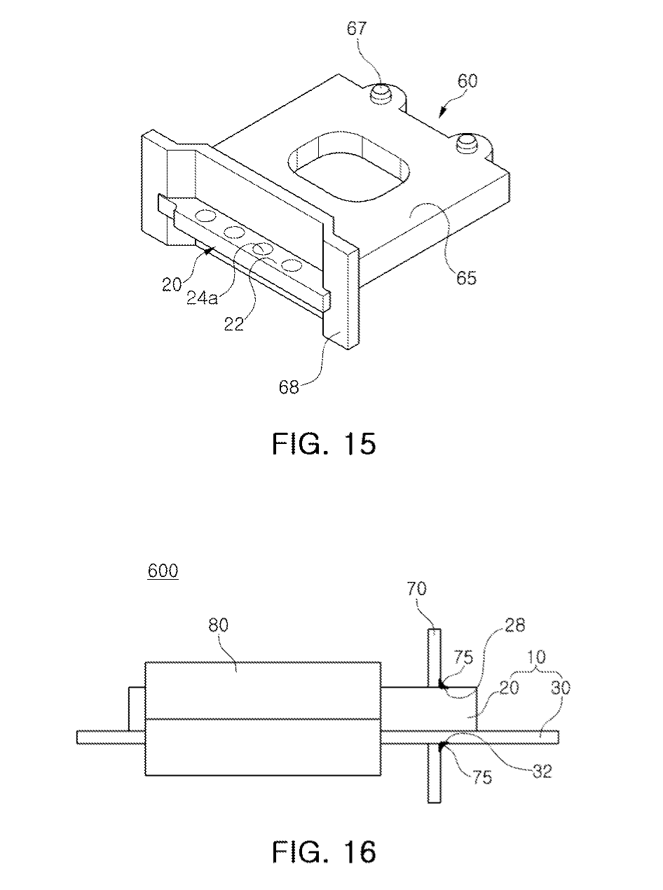

FIG. 14 is a perspective view schematically illustrating a coil component according to another exemplary embodiment in the present inventive concept; and FIG. 15 is a perspective view schematically illustrating a first coil part of the coil component illustrated in FIG. 14.

Referring to FIGS. 14 and 15, a coil component 500 according to the present exemplary embodiment may have the molding part 60 formed in the first coil part 20, similarly to the exemplary embodiment in the FIG. 11.

The molding part 60 according to the present exemplary embodiment may include an embedding part 65, a flange part 68, and a coupling protrusion 67.

The embedding part 65 may embed the pattern part 23 in FIG. 2 having the first coil pattern formed therein in the first coil part 20. Therefore, the terminal part 22 of the first coil part 20 may be exposed outwardly of the embedding part 65.

The flange part 68 may be formed around the terminal part 22 exposed outwardly of the embedding part 65. The flange part 68 may be formed to be extended outwardly, adjacently to the terminal part 22 of the first coil part 20. For example, the flange part 68 may be formed to be perpendicular to respective surfaces of the first coil part 20 and protrude outwardly.

The above-mentioned flange part 68 may be disposed between the terminal part 22 of the first coil part 20 and the core 80, and may secure an insulation distance and a creeping distance therebetween.

In addition, a portion of the flange part 68 may be disposed so as to penetrate through the main substrate 30. Therefore, the insulation distance and the creeping distance between the terminal pad (not illustrated) of the main substrate 30 and the second coil part 20 may be easily secured.

The coupling protrusion 67 may be a protrusion protruding from one surface of the embedding part 65, and may be inserted into the main substrate 30. In addition, correspondingly thereto, the main substrate 30 may be provided with a coupling groove (not illustrated) into which the coupling protrusion 67 is inserted.

Therefore, the molding part 60 may be coupled to the main substrate 30 by inserting the coupling protrusion 67 into the coupling groove of the main substrate 30, and consequently, the first coil part 20 embedded in the molding part 60 and the second coil part, that is, the main substrate 30, may be invariably coupled to each other at a preset precise position.

In addition, the first coil part 20 according to the present exemplary embodiment may have the terminal part 22 having only the terminal pad 24a formed thereon. Therefore, the terminal pad 24a may be bonded to the terminal pad (not illustrated) of the main substrate 30 and may be mounted thereon using only a conductive adhesive such as solder without using the terminal pins.

Meanwhile, since the manufacturing method of the coil component 500 according to the present exemplary embodiment is similar to the manufacturing method of the coil component illustrated in FIG. 11 described above, a description thereof will be omitted.

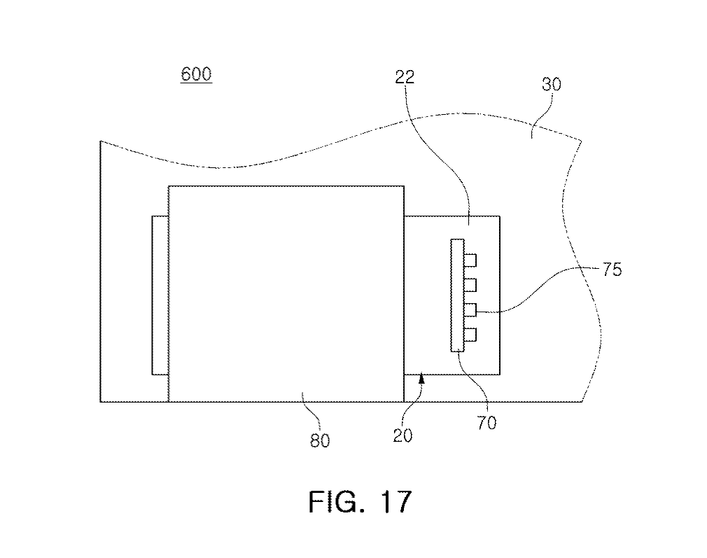

FIG. 16 is a side view schematically illustrating a coil component according to another exemplary embodiment in the present inventive concept; and FIG. 17 is a plan view of the coil component illustrated in FIG. 16.

A coil component 600 according to the present exemplary embodiment may have a hole formed in the terminal part 22 of the first coil part 20 including the stacked substrate, and may have a hole formed in the main substrate 30, that is, the second coil part. In addition, a terminal substrate 70 may be inserted into the hole of the first coil part 20 and the hole of the second coil part 30 while penetrating therethrough. The terminal substrate 70 may be a conventional PCB, but other substrates may also be used.

The terminal substrate 70 may have a wiring pattern (not illustrated) formed thereon, wherein the wiring pattern electrically connects a coil pattern (not illustrated) of the first coil part 20 and a wiring pattern (not illustrated) of the main substrate 30 to each other.

Therefore, the first coil part 20 may have a terminal pad 28 for an electrical connection to the terminal substrate 70 formed on one surface of the first coil part 20, that is, an upper surface of the first coil part 20, and the main substrate 30 may have a terminal pad 32 for an electrical connection to the terminal substrate 70 formed on a lower surface of the first coil part 20. Therefore, the terminal substrate 70 may physically and electrically connect the first coil part 20 and the main substrate 30 to each other by conductive adhesives 75 such as solders.

The coil component according to the present exemplary embodiment as described above may secure the insulation distance and the creeping distance between the terminal pad of the first coil part or the terminal pad of the second coil part, and the core by the terminal substrate. Therefore, the insulating cover or the molding part described above may be omitted, as necessary.

The coil component and the manufacturing method thereof according to the present inventive concept described hereinbefore are not limited to the above-mentioned exemplary embodiments, but may be variously applied.

In addition, although the coil component applied to an AC-DC converter used in the power supply apparatus is described in the present exemplary embodiment byway of example, the present inventive concept is not limited thereto, but may be widely applied to various electronic components and electronic devices as long as the coil component uses the coil and core.

As set forth above, according to exemplary embodiments of the present inventive concept, since the coil component has the coil not wound around a bobbin but provided in the form of the stacked substrate, the size of the coil component and costs for manufacturing the coil component may be significantly reduced.

In addition, since the insulation between the primary and secondary sides of the coil component may be secured by the insulating cover or the molding part, the coil component capable of performing the AC-DC transformation while having the relatively small size may be provided.

While exemplary embodiments have been shown and described above, it will be apparent to those skilled in the art that modifications and variations could be made without departing from the scope of the present invention as defined by the appended claims.

What is claimed is:

1. A coil component, comprising:
a first coil part including a stacked substrate on which a first coil pattern is formed;
a second coil part including a main substrate on which a second coil pattern is formed and a plurality of electronic components are mounted;
a core penetrating through the first and second coil parts and coupled to the first and second coil parts; and
an insulating member securing an insulation distance between the second coil pattern and the electronic components mounted on the main substrate.

2. The coil component of claim 1, wherein the insulating member is an insulating cover including at least one side wall, the side wall being interposed between the second coil pattern and the electronic components.

3. The coil component of claim 2, wherein the insulating member has the side wall interposed between terminal pins bonded to the first coil part and the second coil pattern of the second coil part.

4. The coil component of claim 3, wherein the main substrate is provided with a terminal pad to which the terminal pins are bonded and a cut part performing cutting between the terminal pad and the second coil pattern, and
the side wall of the insulating member is disposed to be inserted into the cut part.

5. The coil component of claim 1, wherein the electronic components mounted on the main substrate include primary side electronic components and secondary side electronic components, and
the insulating member is interposed between the primary side electronic components and the secondary side electronic components to secure an insulation distance therebetween.

6. The coil component of claim 1, wherein the stacked substrate includes a pattern part having the first coil pattern formed therein, and a terminal block formed to protrude from the pattern part in a shape of ‘ [symbol] ’, and the insulating member is interposed between the terminal block and the pattern part.

7. The coil component of claim 6, wherein the stacked substrate has the terminal block having a plurality of terminal holes formed therein and terminal pins formed on the main substrate are inserted into the terminal holes.

8. The coil component of claim 1, further comprising insulating films formed to have each area greater than an area of one surface of the stacked substrate and bonded to both surfaces of the stacked substrate, respectively.

9. The coil component of claim 8, wherein insulation between the stacked substrate and an inner surface of the core is secured by the insulating film.

10. The coil component of claim 1, wherein the insulating member is a molding part formed of an insulating material accommodating the first coil part therein.

11. The coil component of claim 10, wherein the stacked substrate has a pattern part having the first coil pattern formed thereon and accommodated in the molding part, and a terminal part exposed outwardly of the molding part.

12. The coil component of claim 10, wherein the molding part includes a locking protrusion protruding from one surface of the molding part to be mechanically coupled to the core.

13. The coil component of claim 10, wherein the locking protrusion of the molding part penetrates through the main substrate to be coupled to the core.

14. The coil component of claim 10, wherein the molding part includes:
an embedding part exposing a terminal part of the first coil part outwardly and embedding a portion in which the first coil pattern is formed; and
a flange part extended outwardly from the embedding part.

15. The coil component of claim 14, wherein the flange part is disposed to penetrate through the main substrate.

16. The coil component of claim 14, wherein the flange part is disposed between the terminal part of the first coil part and the core to secure insulation therebetween.

17. The coil component of claim 14, wherein the molding part further includes at least one coupling protrusion formed to protrude from one surface of the embedding part and inserted into a coupling groove formed in the main substrate.

18. A coil component, comprising:
a first coil part including a stacked substrate on which a first coil pattern is formed;
a second coil part including a main substrate on which a second coil pattern is formed;
a core penetrating through the first and second coil parts and coupled to the first and second coil parts;
terminal pins electrically connecting the first coil pattern and the main substrate to each other; and
an insulating member interposed between the terminal pins and the core to secure insulation therebetween.

19. A coil component, comprising:
a first coil part including a stacked substrate on which a first coil pattern is formed;
a second coil part including a main substrate on which a second coil pattern is formed;
a core penetrating through the first and second coil parts and coupled to the first and second coil parts;
terminal pins electrically connecting the first coil pattern and the main substrate to each other; and
an insulating member interposed between the terminal pins and the second coil pattern to secure insulation therebetween.

20. A coil component, comprising:
a main substrate on which primary side electronic components and secondary side electronic components are mounted together and a second coil pattern is formed; and
a stacked substrate on which the first coil pattern is formed and mounted on the main substrate,
wherein the stacked substrate and the primary side electronic components are classified as a primary region, and
the second coil pattern and the secondary side electronic components are classified as a secondary region.

21. The coil component of claim 20, further comprising an insulating member partially interposed between the primary region and the secondary region to secure insulation therebetween.

22. The coil component of claim 20, further comprising a core penetrating through the main substrate and the stacked substrate and coupled thereto, wherein the core is classified as the secondary region.

23. A coil component, comprising:
a stacked substrate on which a primary coil is formed; and
a main substrate on which a secondary coil is formed and electronic components on a primary side and electronic components on a secondary side are mounted together.

24. A coil component, comprising:
a stacked substrate on which three or more wiring pattern layers are stacked to form a first coil pattern thereon;
a main substrate having two wiring pattern layers stacked on both surfaces of the main substrate to form a second coil pattern thereon; and
a core penetrating through the stacked substrate and the main substrate and coupled thereto.

25. A coil component, comprising:
a first coil part including a stacked substrate on which a first coil pattern is formed;
a second coil part including a main substrate on which a second coil pattern is formed;
a core penetrating through the first and second coil parts and coupled to the first and second coil parts; and
a terminal substrate penetrating through the first and second coil parts, coupled to the first and second coil parts, and electrically connecting the first coil pattern to the main substrate.

26. The coil component of claim 25, wherein the terminal substrate is electrically connected to a terminal pad formed on an upper surface of the stacked substrate and is electrically connected to a terminal pad formed on a lower surface of the main substrate.

27. A manufacturing method of a coil component, the method comprising:
preparing a main substrate on which electronic components on a primary side and electronic components on a secondary side are mounted and a second coil pattern is formed;
coupling a coil assembly to the main substrate, the coil assembly having a molding part partially accommodating a stacked substrate on which a first coil pattern is formed; and
coupling a core to the main substrate and the coil assembly while penetrating therethrough.
